(19) United States
(12) Patent Application Publication
(10) Pub. No.: US 2019/0239378 A1
(43) Pub. Date: Aug. 1, 2019

(54) CIRCUIT BOARD FIXATION STRUCTURE AND ELECTRICAL APPARATUS

(71) Applicant: SUMITOMO WIRING SYSTEMS, LTD., Yokkaichi-shi, Mie (JP)

(72) Inventors: Satoru CHAEN, Yokkaichi (JP); Keiichi OGAWA, Yokkaichi (JP); Hiroshi KOJIMA, Yokkaichi (JP)

(73) Assignee: SUMITOMO WIRING SYSTEMS, LTD., Yokkaichi-shi, Mie (JP)

(21) Appl. No.: 16/318,341

(22) PCT Filed: Jul. 18, 2017
(86) PCT No.: PCT/JP2017/025876

§ 371 Date: Jan. 16, 2019

(30) Foreign Application Priority Data
Jul. 29, 2016 (JP) 2016-149901

(51) Int. Cl. H05K 7/14; H05K 1/02

(52) U.S. Cl. CPC H05K 7/1427; H05K 2201/10409; H05K 1/02

(57) ABSTRACT

A circuit board fixation structure includes a screw, an inner tubular section having a threaded hole into which the screw is threaded, and an outer tubular section. The outer tubular section includes an abutted section the head of the screw, and a pressing section. A large-diameter section is fixed relative to an outer peripheral surface of the inner tubular section, and has a diameter dimension is greater than an outer dimension of the inner tubular section. A circuit board is provided with a through hole with an inner diameter dimension that is greater than an outer dimension of the inner tubular section and smaller than the outer dimension of the large-diameter section. The circuit board is interposed between the pressing section of the outer tubular section and the large-diameter section in a state in which the inner tubular section is inserted through the through hole.

A technology disclosed in this specification relates to a circuit board fixation structure and an electrical apparatus.

### BACKGROUND

In an electrical connection box, a board is arranged between a main body case and a lower case. The board is fixed to one of the main body case and the lower case. An example of this fixation structure of a board is disclosed in Patent Reference 1.

In Patent Reference 1, a fixing boss stands erect on a case main body. By (i) inserting a screw into screw holes that are arranged in a reinforcement plate, a flexible plate, and a spacer, from the reinforcement place side and (ii) screwing the screw into a fixing hole of the fixing boss, the reinforcement plate, the flexible plate, and the spacer are fixed to the case main body.

Patent Reference 1: P2011-250569A

### SUMMARY

However, according to such a fixation structure of the board, a screw seat face presses the reinforcement plate, and the pressing force is applied as-is to a flexible board overlapped with the reinforcement plate. Because of this, at a surrounding portion of the fixing hole of the flexible board into which the screw is inserted, a pressing force is received at the portion corresponding to the screw seat surface, and at the portion that surrounds that portion, and there is a possibility that distortion, crinkling, or the like is generated. Circuit wiring cannot be performed in the portion of the flexible board in which such distortion, crinkling, or the like is generated. Thus, the mounting area is reduced.

Technology disclosed in this specification was made based on the above situation. An object is to provide a fixation structure of a circuit board that improves wiring density of the circuit board, and an electrical apparatus using this.

A circuit board fixation structure related to a technology disclosed in this specification is provided with:

a screw having a head section at one end of an axial section provided with a screw thread, the head section having a diameter larger than a diameter of the axial section;

an inner tubular section having a threaded hole into which the axial section of the screw is threaded;

an outer tubular section that is provided with (i) a fitting hole that externally fits to the inner tubular section, and of which an inner diameter dimension is greater than an outer dimension of the inner tubular section, (ii) an abutted section, provided at one end of the outer tubular section, that is abutted by the head section of the screw in a state in which the axial section of the screw is threaded into the threaded hole of the inner tubular section and (iii) a pressing section at another end of the outer tubular section;

a large-diameter section that is suppressed from moving relative to an outer peripheral surface of the inner tubular section and of which a diameter dimension is greater than an outer dimension of the inner tubular section; and a circuit board that (i) is provided with a through hole with an inner diameter dimension that is greater than an outer dimension of the inner tubular section and smaller than the outer dimension of the large-diameter section and (ii) is interposed between the pressing section of the outer tubular section and the large-diameter section in a state in which the inner tubular section is inserted through the through hole.

According to the above structure, the following operation effects can be obtained. In a state in which the inner tubular section is inserted through the through hole of the circuit board, the circuit board is not inserted beyond the large-diameter section. When the outer tubular section is externally fitted over the inner tubular section and the axial section of the screw is fitted into the fitting hole of the inner tubular section, the head section of the screw abuts the abutted section of the outer tubular section. Thereby, the outer tubular section is pressed by the head section of the screw. Then, the circuit board is interposed between the pressing section of the outer tubular section and the large-diameter section. Thereby, the circuit board can be fixed.

At this time, the circuit board is interposed between the large-diameter section and the pressing section. Thus, by changing the dimensions of the large-diameter section and the pressing section, the area of the region in which pressure is applied to the circuit board can be made small. As a result, a region in which an electrically conductive pattern of the circuit board cannot be formed can be made small. Thus, wiring density of the circuit board can be improved.

In addition to the above structure, the large-diameter section can be integrally formed with the outer peripheral surface of the inner tubular section. According to this structure, compared to a case in which separate components are used for the large-diameter section and the inner tubular section, the number of components can be reduced.

The following mode is preferable as an implementation mode of the technology disclosed in this specification.

It is preferable that the large-diameter section is integrally formed with the outer peripheral surface of the inner tubular section.

According to this structure, compared to a case in which separate components are used for the large-diameter section and the inner tubular section, the number of components can be reduced.

Furthermore, an electrical apparatus disclosed in this specification is provided with:

the above circuit board fixation structure;

a first case having a first bottom plate section having the outer tubular section; and

a second case having a second bottom plate section having the inner tubular section, wherein:

the first and second cases are integrally assembled by threading the axial section of the screw into the threaded hole of the inner tubular section.

According to the above structure, wiring density of the circuit board provided by the electrical apparatus can be improved.

The following mode is preferable as an implementation mode of the technology disclosed in this specification.

It is preferable that a first claw section is formed at a first side wall section that stands erect from a side edge of the first bottom plate section, and that a second claw section that engages with the first claw section, at a position corresponding to the first claw section, is provided at a second side wall section that stands erect from a side edge of the second bottom plate section.

According to the above structure, by engaging the first claw section of the first case with the second claw section of the second case, the first case and the second case can be temporarily assembled prior to screwing.

It is preferable that the pressing section of the outer tubular section abuts the circuit board in a state in which the first and second claw sections are engaged with each other.

According to the above structure, in a state in which the first claw section of the first case and the second claw section of the second case are engaged with each other, the circuit board is pressed against the large-diameter section side by the pressing section of the outer tubular section. Thereby, in a state in which the first case and the second case are temporarily assembled, the circuit board can be suppressed from rattling.

According to this invention, a fixation structure of a circuit board can be realized in a simple configuration without reducing the mounting area of the circuit board, and wiring density of the circuit board can be improved.

### BRIEF DESCRIPTION OF THE DRAWINGS

FIG. 1 is a plan view showing an electrical apparatus related to an embodiment.

FIG. 2 is a perspective view showing a first case.

FIG. 3 is a perspective view showing a second case.

FIG. 4 is a perspective view showing a first case in which a second case and a circuit board are arranged.

FIG. 5 is a perspective view showing first and second cases temporarily assembled together.

FIG. 6 is a cross-sectional view showing a first case in which a circuit board is arranged.

FIG. 7 is a cross-sectional view showing first and second cases temporarily assembled together.

FIG. 8 is a cross-sectional view showing first and second cases screwed together, and is a VIII-VIII cross-sectional view of FIG. 1.

FIG. 9 is a cross-sectional view showing first and second cases in a comparative example.

### DETAILED DESCRIPTION OF EMBODIMENTS

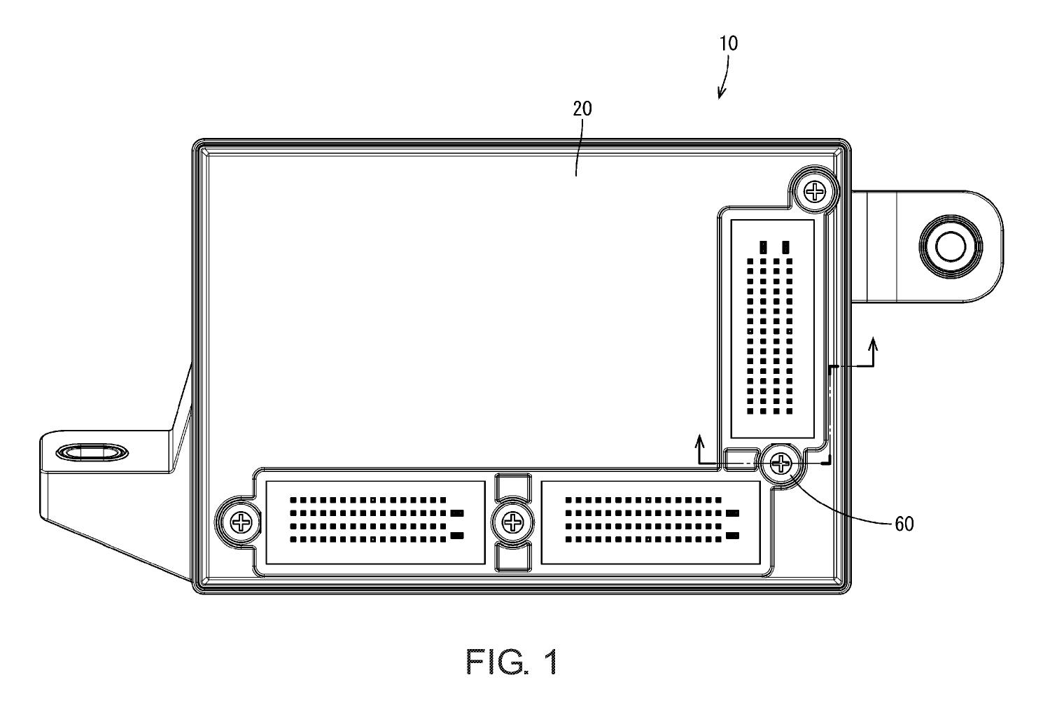

An embodiment of the technology disclosed in this specification is explained with reference to FIGS. 1-8. In this embodiment, an electrical apparatus 10 shown in FIGS. 1, 4, and 5 is, for example, an ECU (Electronic Control Unit) and supplies power to various on-board electric equipment from a power source such as a battery, controls power supply, and the like.

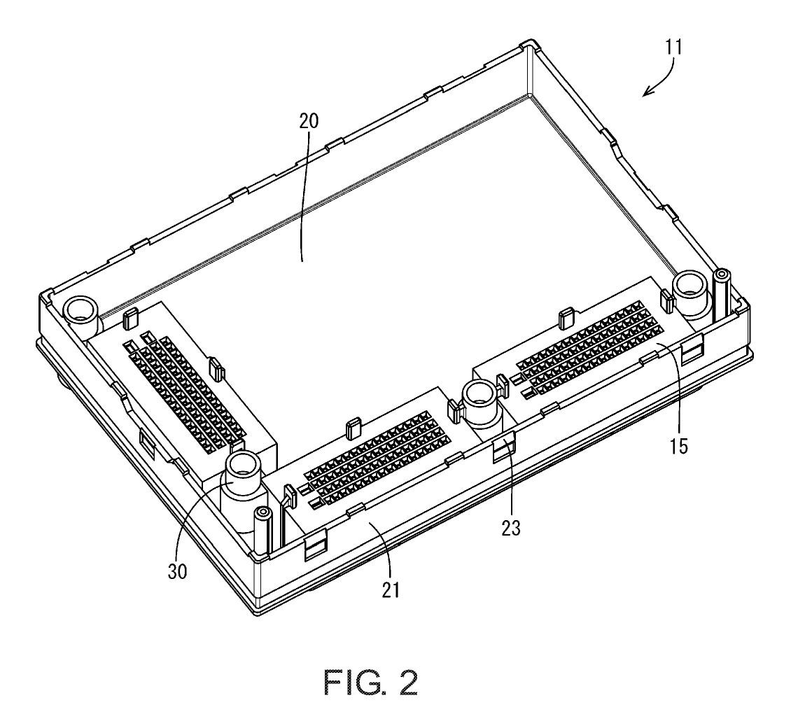

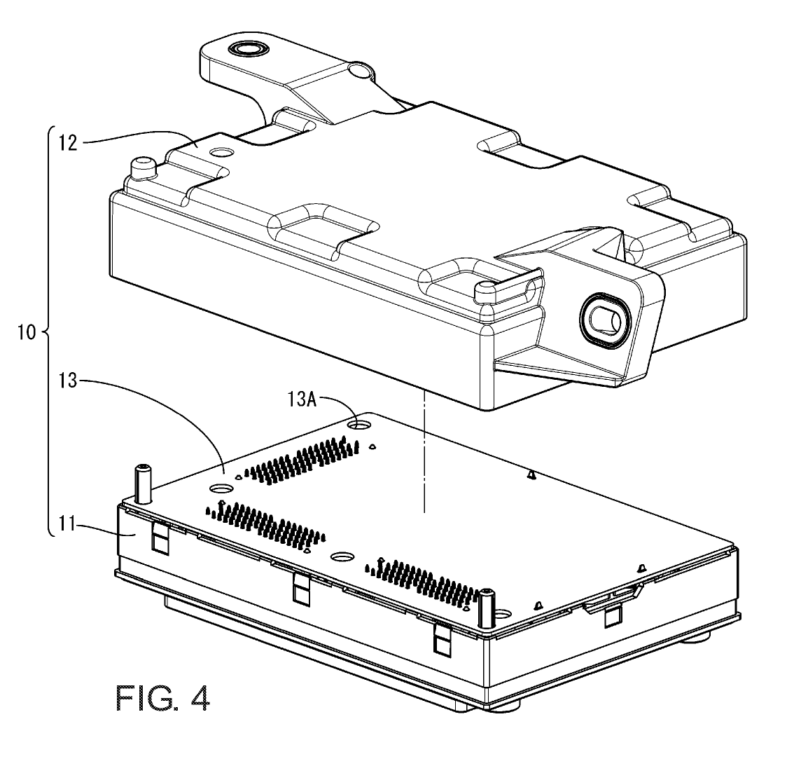

As shown in FIG. 4, an electrical apparatus 10 is provided with (i) a plate-shaped circuit board 13, (ii) a first case 11 at which the circuit board 13 is arranged, and (iii) a second case 12 fixed to the first case 11 so as to cover the circuit board 13. A plurality of connectors 15 are arranged in the first case 11, as shown in FIG. 2.

As shown in FIG. 4, the circuit board 13 has a substantially rectangular shape. On both or one of front and rear surfaces of the circuit board 13, an undepicted electrically conductive pattern is formed, using a printed circuit technology. Additionally, on the circuit board 13, a plurality of board holes 13A (through holes) are arranged, which are used when the circuit board 13 is fixed to the respective first and second cases 11 and 12.

As shown in FIG. 2, the first case 11 has a substantially box shape and has (i) a first bottom plate section 20 that has a substantially rectangular shape and (ii) first side wall sections 21 that are formed so as to stand erect from four edges of the first bottom plate section 20. On outer surfaces of the first side wall sections 21, a plurality of first claw sections 23 are arranged that are used for temporary assembly with the second case 12. Furthermore, a plurality of first tubular sections 30 are formed protruding from the first bottom plate 20. In this embodiment, four first tubular sections 30 are arranged in the vicinity of the two first side wall sections 21 neighboring places at which the connectors 15 are arranged.

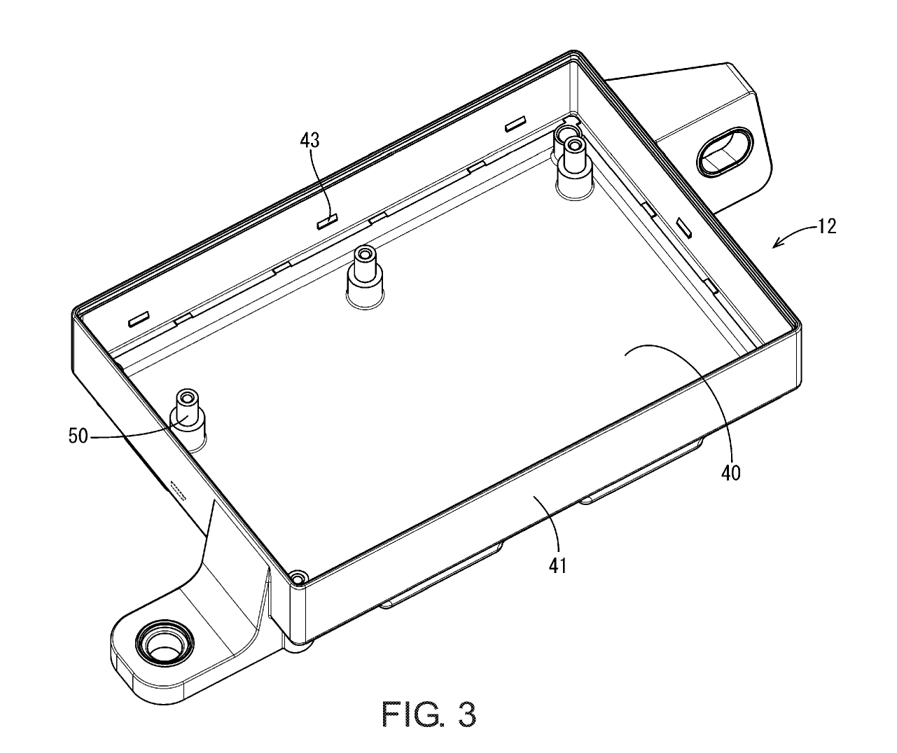

As shown in FIG. 3, the second case 12 has the same substantially box shape as the first case 11 and has (i) a second bottom plate section 40 that has a substantially rectangular shape and (ii) second side wall sections 41 that are formed so as to stand erect from four edges of the second bottom plate section 40. On inner surfaces of the second side wall sections, second claw sections 43 are arranged that engage with the first claw sections 23 of the first case 11. The number of the second claw sections 43 is the same as the number of the first claw sections 23. Additionally, a plurality of second tubular sections 50 are formed protruding from the second bottom plate section 40. The same number of the second tubular sections 50 as the first tubular sections 30 are arranged at locations corresponding to the first tubular sections 30.

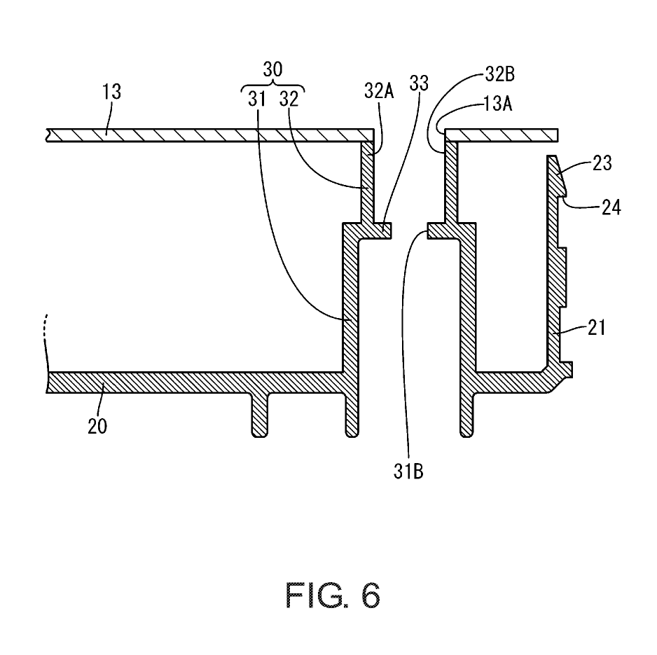

Next, with reference to FIGS. 6-8, a structure of a circuit board fixation structure 1 is explained in detail.

A structure of the first tubular sections 30 of the first case 11 is explained. The first tubular sections 30 have a cylindrical shape having a hollow therein and are each provided with (i) a first large-diameter section 31 that is arranged at a base end side in the vicinity of the first bottom plate section 20 and (ii) a first small-diameter section 32 (outer tubular section) that is arranged at a tip end side of the first tubular section 30 connecting with the first large-diameter section 31. A diameter dimension of the first large-diameter section 31 is greater than that of the first small-diameter section 32. The first large-diameter section 31 is open at the first bottom plate section 20 and has a first bottom plate hole 31C.

At a connecting section between the first large-diameter section 31 and the first small-diameter section 32, at one end of the first small-diameter section 32, a fixation section 33 (abutted section) is arranged protruding inward from an inner peripheral surface of the first tubular section 30. The fixation section 33 is arranged along the entire circumference of the first large-diameter section 31 and the first small-diameter section 32. A first screw insertion hole 31B is formed at an inner periphery of the fixation section 33.

A tip end side of the first small-diameter section 32 is open, and a fitting hole 32B (fitting hole) is arranged that inserts into the inside of a second small-diameter section 52 that will be described later. At a tip end that is the other end of the first small-diameter section 32, a first board pressing section 32A (pressing section) is provided.

The first claw sections 23 are explained, which are arranged at the first side wall sections 21 of the first case 11. As shown in FIG. 2, in this embodiment, the first claw sections 23 are arranged at the outer surfaces of the four first side wall sections 21. As shown in FIG. 6, the first claw sections 23 are arranged at tip ends of the first side wall sections 21 and are formed in a tapered shape toward the tip end of the first side wall sections 21.

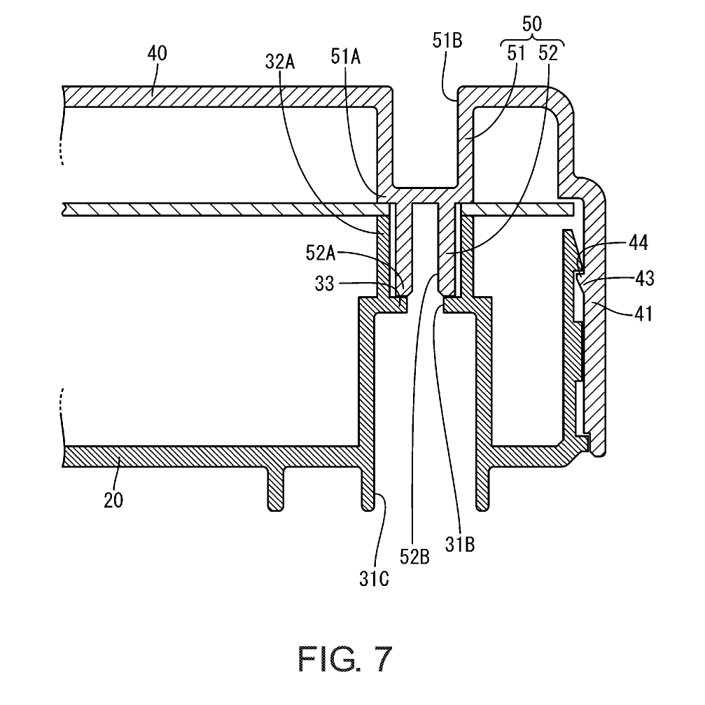

A structure of the second tubular sections 50 of the second case 12 is explained. As shown in FIG. 7, the second tubular sections 50 have a cylindrical shape having a hollow therein and are each provided with (i) a second large-diameter section 51 (large diameter section) that is arranged at a base end side in the vicinity of the second bottom plate section 40 and (ii) a second small-diameter section 52 (inner tubular section) that is arranged at a tip end side of the second tubular section 50 connecting with the second large-diameter section 51. A diameter dimension of the second large-diameter section 51 is greater than that of the second small-diameter section 52. The second large-diameter section 51 is open at the second bottom plate section 40 and is provided with a second bottom plate hole 51B. Additionally, the second large-diameter section 51 is constituted so as to be suppressed from moving relative to an outer peripheral surface of the second small-diameter section 52. In this embodiment, the second large-diameter section 51 is integrally formed with the outer peripheral surface of the second small-diameter section 52, but an inner space of the second large-diameter section 51 is not in communication with an inner space of the second small-diameter section 52.

At an outer peripheral surface of a connecting section between the second large-diameter section 51 and the second small-diameter section 52, the second large-diameter section 51 protrudes outward beyond the second small-diameter section 52 and forms a step section. The step section is a second board pressing section 51A. A tip end of the second small-diameter section 52 is open, and the second small-diameter section 52 is provided at the inside with a threaded hole 52B (threaded hole) into which a screw 60 having a screw thread is threaded. A tip end of the second small-diameter section 52 is a second tubular abutting section 52A and abuts the fixation section 33 in a state in which the screw 60 is threaded into the threaded hole 52B. Specifically, in a state in which the screw 60 is threaded into the threaded hole 52B, the second tubular abutting section 52A abuts a surface of the fixation section 33 at the fitting hole 32 side.

An inner diameter dimension of the first small-diameter section 32 is greater than an outer dimension of the second small-diameter section 52. The first small-diameter section 32 is externally fitted over the second small-diameter section 52.

The second claw sections 43 arranged at the second side wall sections 41 of the second case 12 are explained. As shown in FIG. 3, in this embodiment, the second claw sections 43 are arranged at inner peripheral surfaces of four second side wall sections 41. As shown in FIG. 7, the second claw sections 43 are arranged protruding inward at a central portion of the second side wall sections 41 and are incliningly formed so as to come down toward the tip ends of the second side wall sections 41.

Next, with reference to FIGS. 4-8, a board fixation structure in a process of assembling the first case 11 and the second case 12 is explained.

First, as shown in FIGS. 4 and 6, the circuit board 13 is placed on the first case 11 so as to match the respective fitting holes 32B corresponding to the respective board holes 13A. After that, as shown in FIG. 7, the respective second small-diameter sections 52 are inserted into the corresponding fitting holes 32B via the board holes 13A, and the second case 12 is positioned with respect to the first case 11.

As shown in FIG. 7, the first side wall sections 21 and the second side wall sections 41 are arranged so as to overlap with each other such that the second side wall sections 41 are arranged outward. At this time, the first case 11 and the second case 12 are temporarily assembled by the first claw sections 23 and the second claw sections 43.

In detail, when the first case 11 is assembled to the second case 12, the second side wall sections 41 move downward. Then, inclination surfaces of the second claw sections 43 move along inclination surfaces of the first claw sections 23. When they ride over first claw step sections 24 of the first claw sections 23, they are engaged with second claw step sections 44 of the second claw sections 43. In FIG. 7, in this state, the first case 11 can only move upward, and the second case 12 can only move downward. They cannot move in a direction in which they separate from each other.

When the first case 11 and the second case 12 are thus temporarily assembled together, as shown in FIG. 7, the first screw insertion hole 31B matches the threaded hole 52B, and the threaded hole 52B communicates with the first large-diameter section 31 via the first screw insertion hole 31B. The tip end of the first board pressing section 32A abuts the circuit board 13, and specifically abuts a hole periphery of the board hole 13A. The second board pressing section 51A of the second large-diameter section 51 abuts the circuit board 13, and specifically abuts a hole periphery of the board hole 13A. That is, the circuit board 13 is interposed between the second board pressing section 51A of the second large-diameter section 51 and the first board pressing section 32A. In this state, there is a small gap between the fixation section 33 and the second tubular abutting section 52A.

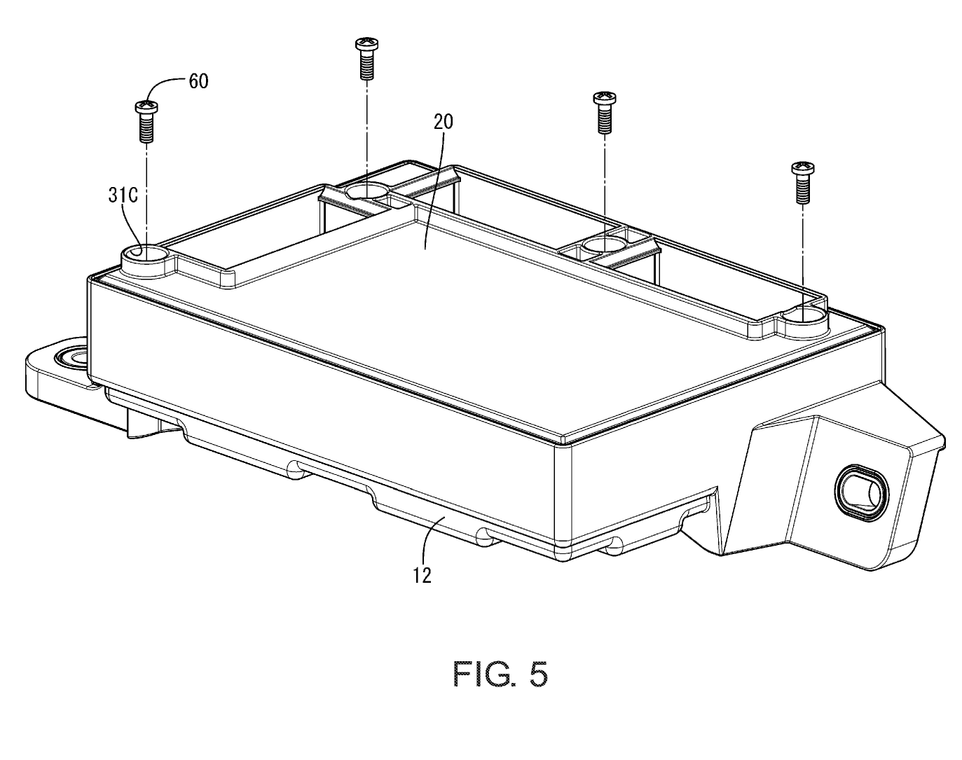

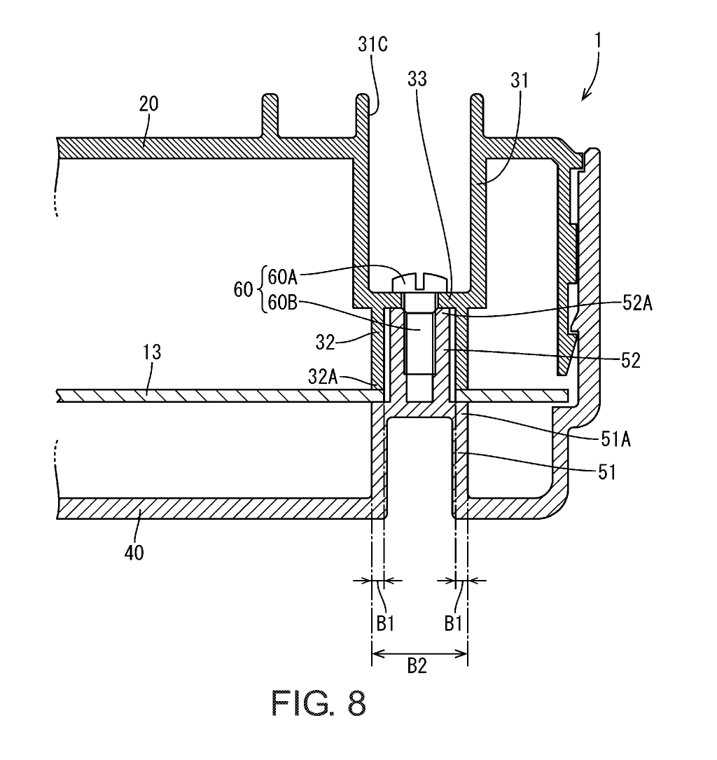

Then, for screw fixing, as shown in FIGS. 5 and 8, the first case 11 and the second case 12 that are temporarily assembled together are inverted in an up-and-down direction. Here, the first case 11 and the second case 12 are temporarily assembled together and do not move in a direction in which they separate from each other. Thus, the first case 11 and the second case 12 do not separate from each other during the inverting operation. Furthermore, the circuit board 13 is interposed between the second board pressing section 51A of the second large-diameter section 51 and the first board pressing section 32A; thus, the circuit board 13 is suppressed from rattling.

In a state in which the first case 11 and the second case 12 are inverted as shown in FIG. 8, the screw 60 is insertingly threaded into the threaded hole 52B via the first screw insertion hole 31B. Then, the small gap between the fixation section 33 and the second tubular abutting section 52A disappears, and the first case 11 and the second case 12 are firmly fixed to each other. Furthermore, the head section 60A presses the fixation section 33 due to threading the screw 60 into the fixation section 33, and the pressing force is transmitted to the first board pressing section 32A via the first small-diameter section 32. Due to the pressing force, the first board pressing section 32A can interposingly fix the circuit board 13 between the first board pressing section 32A and the second board pressing section 51A.

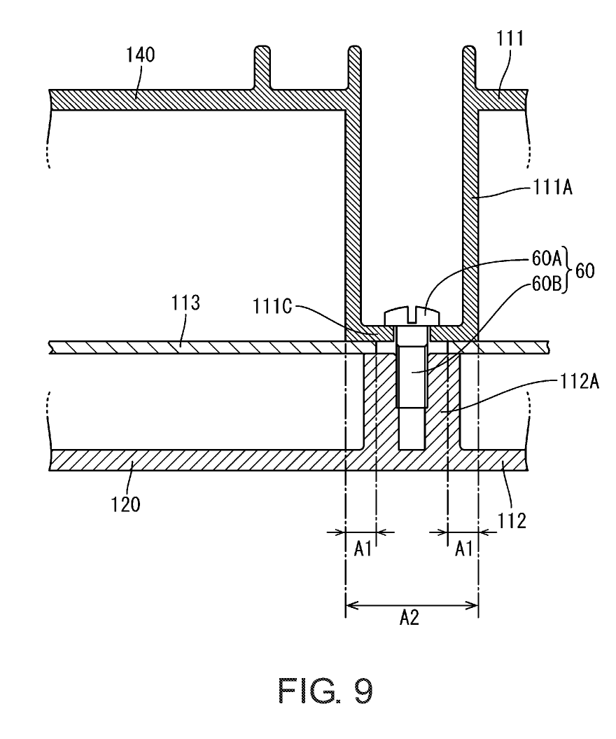

Here, with reference to FIG. 9, a board fixation structure without having the first small-diameter section 32 and the second small-diameter section 52 of this embodiment is explained as a comparative example.

In the comparative example, a screw hole is arranged at an end of a first tubular section 111A that is arranged protruding from a first bottom plate section 140 of a first case 111. A board hole is arranged at a position corresponding to a circuit board 113. A protruding end of a second tubular section 112A that is arranged protruding from the second bottom plate section 120 of the second case 112 is open, and a screw insertion hole is provided therein.

In the comparative example, the circuit board 113 is interposed between a first board pressing section 111C of the first tubular section 111A and the protruding end of the second tubular section 112A. In this state, the screw 60 is threadingly engaged. When the screw 60 is threadingly inserted to a screw insertion hole of the second tubular section 112A via the screw hole and the board hole, the pressing force from the head section of the screw 60 is applied to the first board pressing section 111C, and due to the pressing force, the circuit board 113 is interposingly fixed between the first board pressing section 111C and the protruding end of the second tubular section 112A.

In the comparative example, due to the screw fixing, a pressing force from the first case 11 is applied to an abutting section A1 in which the first case 111 abuts the circuit board 113, and then distortion or the like is generated. Thus, an electrically conductive pattern cannot be formed in the abutting section A1. In the comparative example, the abutting section A1 of the circuit board 113 extends over a wide range in the surrounding of the hole periphery of the board hole, wiring cannot be performed on the circuit board 113 in a range of a diameter A2, and a mounting area of the circuit board 113 becomes small. In the comparative example that is thus described, because a fixing position of the circuit board 113 and a screwing position are near each other, the abutting section A1 in which the first case 111 abuts the circuit board 113 becomes large.

Meanwhile, in this embodiment, as shown in FIG. 8, by having the first small-diameter section 32 and the second small-diameter section 52 arranged, the screwing position to which a pressing force applied by fitting the screw 60 applies can be separate from the fixing position of the circuit board in which the first board pressing section 32A of the first small-diameter section 32 is abutted against the board. Because of this, an abutting section B1 of the circuit board 13 is within a small range surrounding the hole periphery of the board hole 13A, and the range in which wiring cannot be performed is within a small range of a diameter B2.

In this embodiment, the circuit board 13 can be fixed by using the screw 60 of the same size as the screw used in the structure of the comparative example, and a range can be reduced in which an electrically conductive pattern cannot be formed at the circuit board 13. Thus, a large mounting area can be assured.

According to this embodiment, in a state in which the second small-diameter section 52 is inserted through the board hole 13A of the circuit board 13, the circuit board 13 is not inserted beyond the second large-diameter section 51. When the first small-diameter section 32 is externally fitted, and the axial section 60B of the screw 60 is threaded into the threaded hole 52B of the second small-diameter section 52, the head section 60A of the screw 60 abuts the fixation section 33 of the first small-diameter section 32. Thereby, the first small-diameter section 32 is pressed by the head section 60A of the screw 60. Then, the circuit board 13 is interposed between the first board pressing section 32A of the first small-diameter section 32 and the second large-diameter section 51. Thereby, the circuit board 13 can be fixed.

At this time, the circuit board 13 is interposed between the second large-diameter section 51 and the first board pressing section 32A. Thus, by changing the dimensions of the second large-diameter section 51 and the first board pressing section 32A, an area of a region in which pressure is applied to the circuit board 13 can be made small. As a result, a region can be made small in which an electrically conductive pattern of the circuit board 13 cannot be formed. Thus, wiring density of the circuit board 13 can be improved.

Additionally, in this embodiment, the second large-diameter section 51 is integrally formed at the outer peripheral surface of the second small-diameter section 52. Thereby, compared to a case in which a component for the second large-diameter section 51 different from that for the second small-diameter section 52 is used for configuration, the number of components can be reduced.

Furthermore, according to this embodiment, the electrical apparatus 10 is provided with (i) a first case 11 having the first bottom plate section 20 provided with the first small-diameter section 32, and (ii) a second case 12 having the second bottom plate section 40 provided with the second small-diameter section 52. By threading the axial section 60B of the screw 60 into the threaded hole 52B of the second small-diameter section 52, the first case 11 and the second case 12 are integrally assembled together. Thereby, wiring density of the circuit board 13 provided to the electrical apparatus 10 can be improved.

Furthermore, in this embodiment, the first claw sections 23 are formed at the first side wall sections 21 that stand erect from the periphery of the first bottom plate section 20. At the second side wall sections 41 that stand erect from the periphery of the second bottom plate section 40, at positions corresponding to the first claw sections 23, the second claw sections 43 are arranged that engage with the first claw sections 23. Thereby, by engaging the first claw sections 23 of the first case 11 with the second claw sections 43 of the second case 12, the first case 11 and the second case 12 can be temporarily assembled prior to screwing.

Additionally, according to this embodiment, in a state in which the first claw sections 23 and the second claw sections 43 are engaged to each other, the first board pressing section 32A abuts the circuit board 13. Thereby, in a state in which the first claw sections 23 of the first case 11 and the second claw sections 43 of the second case 12 are engaged with each other, the circuit board 13 is pressed against the first large-diameter section 31 (fixation section 33) side by the first board pressing section 32A. Thereby, in a state in which the first case 11 and the second case 12 are temporarily assembled, the circuit board 13 can be suppressed from rattling.

<Other Implementation Modes>

The technology disclosed in this specification is not limited to the embodiment explained above by description and drawings. For example, the following embodiment is also included in the scope of the technology disclosed in this specification.

(1) The electrical apparatus 10 related to this embodiment is an ECU, but it is not limited to this. An electrical connection box can also be used that switches power that is supplied from a power source to an on-board electrical component, and an arbitrary electrical apparatus can be used.

(2) In this embodiment, one electrical apparatus 10 has one circuit board 13, but it is not limited to this. One electrical apparatus 10 can also accommodate a plurality of circuit boards 13.

(3) In this embodiment, in a state in which the first claw sections 23 and the second claw sections 43 are engaged with each other, there is a small gap between the fixation section 33 and the second tubular abutting section 52A, but it is not limited to this. In a state in which the first claw sections 23 and the second claw sections 43 are engaged to each other, the fixation section 33 can abut the second tubular abutting section 52A.

(4) In this embodiment, the electrical apparatus 10 is constituted so as to be provided with the first claw sections 23 and the second claw sections 43, but they can be omitted.

### EXPLANATION OF SYMBOLS

10: Electrical apparatus
11: First case
12: Second case
13: Circuit board
13A: Board holes (through holes)
20: First bottom plate section
21: First side wall sections
23: First claw sections
30: First tubular sections
31: First large-diameter sections
32: First small-diameter sections (outer tubular section)
32A: First board pressing sections (pressing section)
32B: Fitting holes
33: Fixation section (abutted section)
40: Second bottom plate section
41: Second side wall sections
43: Second claw sections
50: Second tubular sections
51: Second large-diameter sections (large-diameter sections)
51A: Second board pressing sections
52: Second small-diameter sections (inner tubular sections)
52A: Threaded holes
60: Screws
60A: Head sections
60B: Axial sections

What is claimed is:

1-5. (canceled)

6. A circuit board fixation structure comprising:
a screw having (i) an axial section provided with a screw thread and (ii) a head section at one end of axial section, the head section having a diameter larger than a diameter of the axial section;
an inner tubular section having a threaded hole into which the axial section of the screw is threaded;
an outer tubular section that is provided with (i) a fitting hole that externally fits to the inner tubular section, and of which an inner diameter dimension is greater than an outer dimension of the inner tubular section, (ii) an abutted section, provided at one end of the outer tubular section, that is abutted by the head section of the screw in a state in which the axial section of the screw is threaded into the threaded hole of the inner tubular section and (iii) a pressing section at another end of the outer tubular section;
a large-diameter section that is fixed relative to an outer peripheral surface of the inner tubular section and of which a diameter dimension is greater than an outer dimension of the inner tubular section; and
a circuit board that (i) is provided with a through hole with an inner diameter dimension that is greater than an outer dimension of the inner tubular section and smaller than the outer dimension of the large-diameter section and (ii) is interposed between the pressing section of the outer tubular section and the large-diameter section in a state in which the inner tubular section is inserted through the through hole.

7. The circuit board fixation structure according to claim 6, wherein:
the large-diameter section is integrally formed with the outer peripheral surface of the inner tubular section.

8. An electrical apparatus including the circuit board fixation structure according to claim 6, comprising:
a first case having a first bottom plate section having the outer tubular section; and
a second case having a second bottom plate section having the inner tubular section, wherein:
in a state in which the first and second cases are assembled together, the axial section of the screw is threadingly engaged with the threaded hole of the inner tubular section.

9. The electrical apparatus according to claim 8, further comprising:
a first claw section provided at a first side wall section that stands erect from a side edge of the first bottom plate section, and
a second claw section that engages with the first claw section at a position corresponding to the first claw section, the second claw section being provided at a second side wall section that stands erect from a side edge of the second bottom plate section.

10. The electrical apparatus according to claim 9, wherein:
the pressing section of the outer tubular section abuts the circuit board in a state in which the first and second claw sections are engaged with each other.
